(19) United States
(12) Patent Application Publication
(10) Pub. No.: US 2017/0011980 A1
(43) Pub. Date: Jan. 12, 2017

(54) SEMICONDUCTOR PACKAGE

(71) Applicant: Samsung Electronics Co., Ltd., Suwon-si (KR)

(72) Inventor: SOONBUM KIM, Suwon-si (KR)

(21) Appl. No.: 15/183,770

(22) Filed: Jun. 15, 2016

(30) Foreign Application Priority Data
Jul. 9, 2015 (KR) 10-2015-0097800

(51) Int. Cl. H01L 23/31; H01L 23/00; H01L 23/495

(52) U.S. Cl. CPC H01L 23/3114; H01L 23/49541; H01L 23/49503; H01L 24/17; H01L 24/49; H01L 24/32; H01L 24/73; H01L 2224/16245; H01L 2224/32245; H01L 2224/48091; H01L 2224/48106; H01L 2224/48245; H01L 2224/73265; H01L 2924/01029; H01L 2924/01013; H01L 2924/01082; H01L 2924/0105; H01L 2924/01079; H01L 2924/01047; H01L 2924/3511; H01L 2924/05442; H01L 2924/05432; H01L 2924/0665; H01L 2924/186; H01L 23/295

(57) ABSTRACT

Disclosed is a semiconductor package including a lead frame with a chip pad and a lead, a semiconductor chip may be disposed on the lead frame, and an encapsulating layer may be disposed on the lead frame. The chip pad may include a center region and an edge region, and the lead may include a first region and a second region between the edge region of the chip pad and the first region of the lead. The encapsulating layer may cover the semiconductor chip and may extend between the chip pad and the lead to cover a bottom surface of the edge region of the chip pad and a bottom surface of the second region of the lead.

### CROSS-REFERENCE TO RELATED APPLICATIONS

This U.S. non-provisional patent application claims priority under 35 U.S.C. §119 to Korean Patent Application No. 10-2015-0097800, filed on Jul. 9, 2015, in the Korean Intellectual Property Office, the entire contents of which are hereby incorporated by reference.

### BACKGROUND

Example embodiments of the inventive concept relate to semiconductor packages and, in particular, to a quad flat no lead (QFN)-type semiconductor package.

Recently, there is a rapidly increasing demand for portable electronic devices, such as cellular phones, MP3 players, and laptop computers. To meet such a demand, it is necessary to reduce physical parameters (e.g., thickness, size, and weight) of a semiconductor package. For example, various package technologies, such as chip scale package (CSP) or quad flat non-lead (QFN) package, are being used to allow for a reduction in thickness and size of a semiconductor package.

### SUMMARY

Example embodiments of the inventive concept provide a highly reliable semiconductor package.

According to an example embodiment of the inventive concept, a semiconductor package may include a lead frame including a chip pad and a lead, the chip pad including a center region and an edge region, the lead including a first region and a second region between the edge region of the chip pad and the first region of the lead, a semiconductor chip may be disposed on the lead frame, and an encapsulating layer may be disposed on the lead frame. The encapsulating layer may cover the semiconductor chip and may extend between the chip pad and the lead to cover a bottom surface of the edge region of the chip pad and a bottom surface of the second region of the lead.

According to another example embodiment of the inventive concept, a semiconductor package may include a lead frame including a chip pad and a lead, the chip pad including a center region and an edge region, the lead including a first region and a second region between the edge region of the chip pad and the first region of the lead, a semiconductor chip may be disposed on the lead frame, an encapsulating layer provided on the lead frame to cover the semiconductor chip and fill a space between the chip pad and the lead, and a resin film provided to cover interfaces between the chip pad and the encapsulating layer and between the lead and the encapsulating layer.

According to another example embodiment of the inventive concept, a semiconductor package may include a lead frame including a chip pad and a lead, a semiconductor chip disposed on a top surface of the chip pad, and a resin material covering the semiconductor chip and extending between the chip pad and the lead to cover a first region of a bottom surface of the chip pad (opposite the top surface of the chip pad) and a bottom surface of the lead.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a plan view illustrating semiconductor packages according to example embodiments of the inventive concept.

FIG. 2 is a sectional view, taken parallel to line I-I′ of FIG. 1, of a semiconductor package according to an example embodiment of the inventive concept.

FIG. 3 is a sectional view, taken parallel to line I-I′ of FIG. 1, of a semiconductor package according to another example embodiment of the inventive concept.

FIG. 4 is a sectional view, taken parallel to line I-I′ of FIG. 1, of a semiconductor package according to another example embodiment of the inventive concept.

FIG. 5 is a sectional view, taken parallel to line I-I′ of FIG. 1, of a semiconductor package according to another example embodiment of the inventive concept.

FIG. 6 is a plan view illustrating a semiconductor package according to an example embodiment of the inventive concept.

FIG. 7 is a sectional view, taken parallel to line II-II′ of FIG. 6, of a semiconductor package according to an example embodiment of the inventive concept.

FIG. 8 is a plan view illustrating a semiconductor package according to an example embodiment of the inventive concept.

FIG. 9 is a sectional view, taken parallel to line III-III′ of FIG. 8, of a semiconductor package according to an example embodiment of the inventive concept.

FIG. 10 is a plan view illustrating a semiconductor package according to an example embodiment of the inventive concept.

FIG. 11 is a sectional view, taken parallel to line IV-IV′ of FIG. 10, of a semiconductor package according to an example embodiment of the inventive concept.

It should be noted that these figures are intended to illustrate the general characteristics of methods, structure and/or materials utilized in certain example embodiments and to supplement the written description provided below. These drawings are not to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. These embodiments may, however, be realized in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein, the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

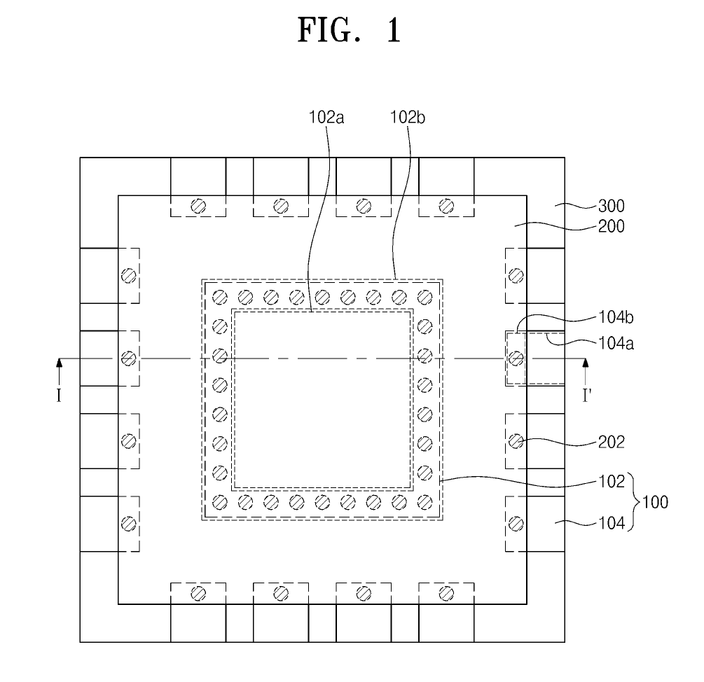

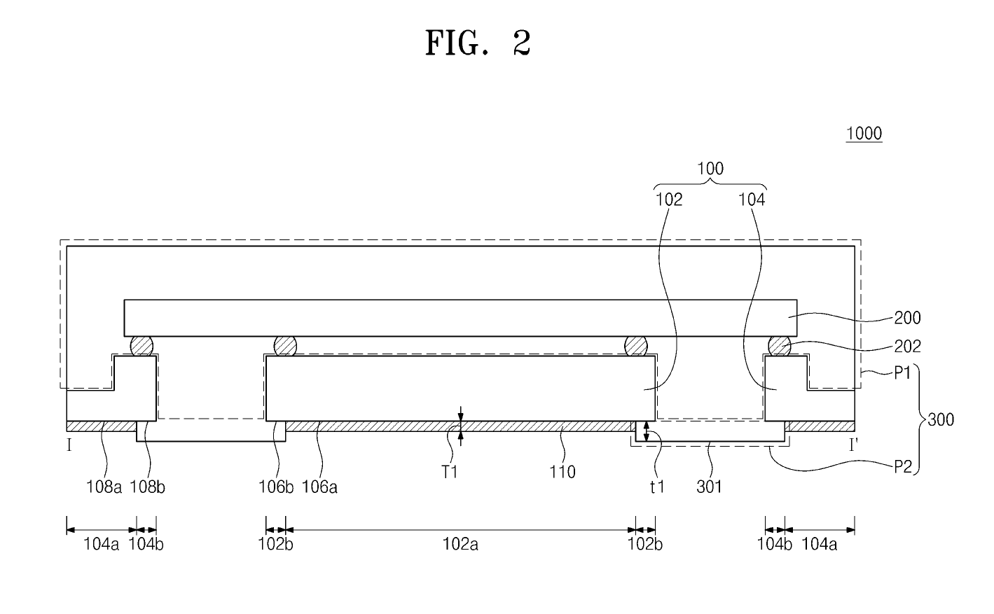

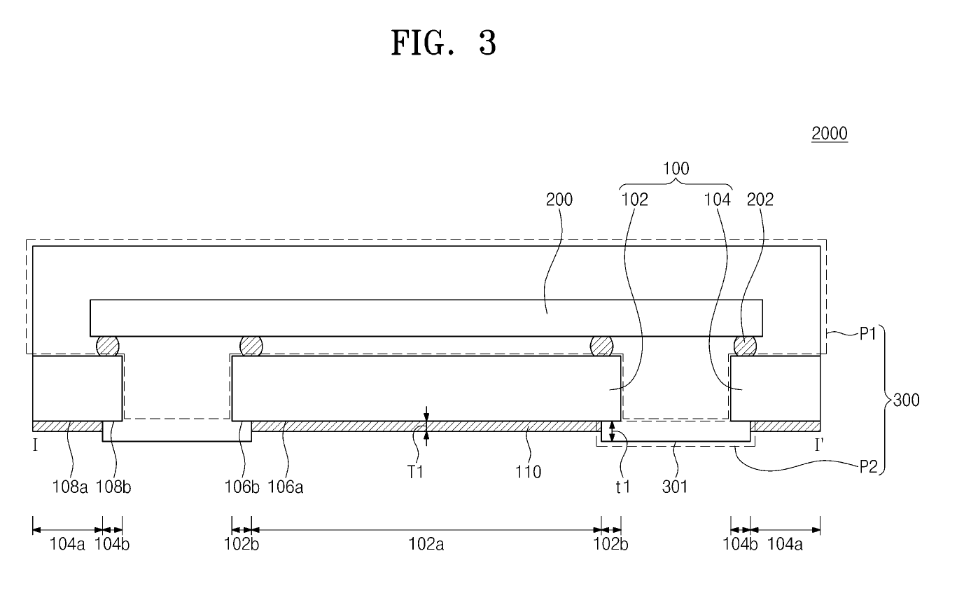

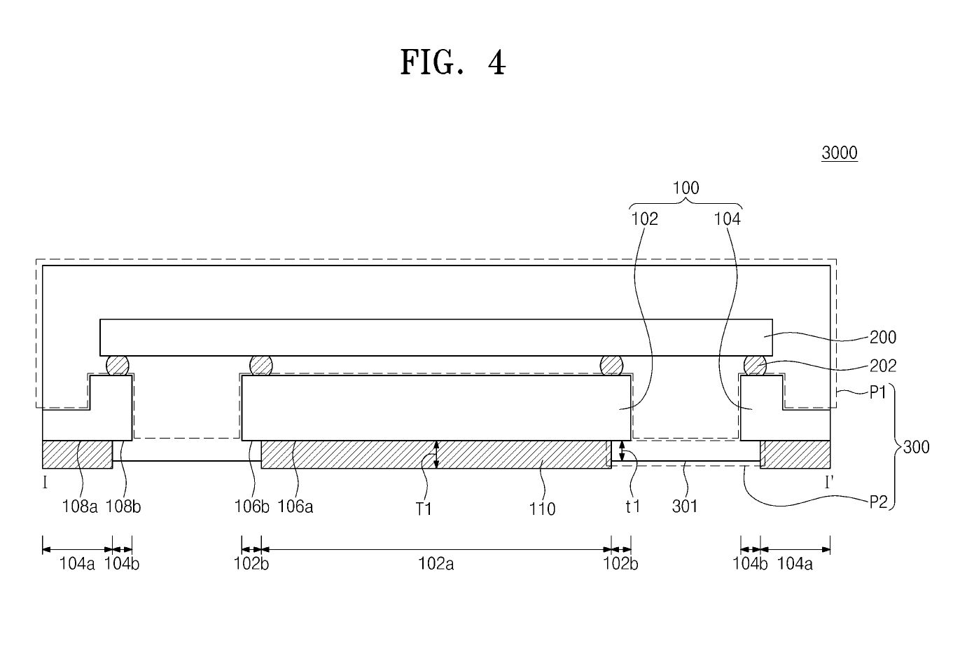

FIG. 1 is a plan view illustrating semiconductor packages according to example embodiments of the inventive concept. FIG. 2 is a sectional view, taken parallel to line I-I′ of FIG. 1, of a semiconductor package according to an example embodiment of the inventive concept. FIG. 3 is a sectional view, taken parallel to line I-I′ of FIG. 1, of a semiconductor package according to another example embodiment of the inventive concept. FIG. 4 is a sectional view, taken parallel to line I-I′ of FIG. 1, of a semiconductor package according to another example embodiment of the inventive concept.

Referring to FIGS. 1 and 2, a semiconductor package 1000 may include a lead frame 100, a semiconductor chip 200, and an encapsulating layer 300. The lead frame 100 may include a chip pad 102 and leads 104. When viewed in plan view, the leads 104 may be disposed spaced apart from the chip pad 102 and may be arranged around the chip pad 102.

The chip pad 102 may include a center region 102a and an edge region 102b around the center region 102a. Each of the leads 104 may include a first region 104a and a second region 104b, and the second region 104b may be adjacent to the chip pad 102. The second region 104b of the lead 104 may be disposed between the edge region 102b of the chip pad 102 and the first region 104a of the lead 104. In some embodiments, the second regions 104b of the leads 104 may be overlapped with the semiconductor chip 200, when viewed in a plan view.

In some embodiments, the first region 104a of the lead 104 may be thinner than the second region 104b of the lead 104, as shown in FIG. 2. In other words, the lead 104 may have an ‘L’-shaped section. The chip pad 102 may have substantially the same thickness as that of the second region 104b of the lead 104. However, in certain embodiments, the first region 104a of the lead 104 may have substantially the same thickness as the second region 104b of the lead 104, like semiconductor package 2000 shown in FIG. 3.

Referring back to FIG. 2, the semiconductor chip 200 may be mounted on the lead frame 100. The semiconductor chip 200 may be attached to the lead frame 100 in a flip-chip bonding manner. In this case, solder balls 202 may be interposed between the semiconductor chip 200 and the chip pad 102, and between the semiconductor chip 200 and the leads 104. In other words, the solder balls 202 may be attached on the chip pad 102 and the leads 104.

The encapsulating layer 300 may be provided on the semiconductor chip 200. The encapsulating layer 300 may cover the semiconductor chip 200. The encapsulating layer 300 may fill a space between the chip pad 102 and the lead 104, and moreover, it may be extended to cover a bottom surface 106b of the edge region 102b of the chip pad 102 and a bottom surface 108b of the second region 104b of the lead 104. The encapsulating layer 300 may be provided to expose the center region 102a of the chip pad 102 and the first regions 104a of the leads 104.

The encapsulating layer 300 may include a first portion P1 and a second portion P2. The first and second portions P1 and P2 of the encapsulating layer 300 may be defined on the basis of a surface of the lead frame 100. For example, the first portion P1 of the encapsulating layer 300 may cover the top surface of the lead frame 100 and the semiconductor chip 200, and may fill a space between the chip pad 102 of the lead frame 100 and the leads 104 of the lead frame 100. The second portion P2 of the encapsulating layer 300 may partially cover the bottom surface of the lead frame 100. For example, the second portion P2 of the encapsulating layer 300 may cover the bottom surface 106b of the edge region 102b of the chip pad 102 and the bottom surface 108b of the second region 104b of each of the leads 104. This may make it possible to suppress or prevent a mechanical stress from being concentrated at interfaces between a bottom surface 301 of the encapsulating layer 300 and a bottom surface of the chip pad 102 and/or between the bottom surface 301 of the encapsulating layer 300 and the bottom surface of the leads 104. Accordingly, it is possible to suppress occurrence of failures at the interfaces (e.g., delamination and/or crack) and thereby to realize a highly reliable semiconductor package.

The encapsulating layer 300 may be formed of, or include, one or more resins (or resin materials), filler-containing epoxy mold compound (EMC) materials, or the like or any combination thereof. The filler may make it possible to reduce a difference in thermal expansion coefficient between the lead frame 100 and the semiconductor chip 200 and thereby to reduce a mechanical stress therebetween. The filler may be formed of, for example, silica or alumina.

A solder plate 110 may be provided on the bottom surface of the lead frame 100. For example, the solder plate 110 may be provided on a bottom surface 106a of the center region 102a of the chip pad 102 and a bottom surface 108a of the first region 104a of the lead 104. The solder plate 110 may be in contact with pads (not shown) provided on a printed circuit board (not shown), when the semiconductor package 1000 is mounted on the printed circuit board. The solder plate 110 may be formed of, or include, at least one metallic material (e.g., copper (Cu), aluminum (Al), lead (Pb), tin (Sb), gold (Au), silver (Ag), etc.). The solder plate 110 may be provided to have a thickness of T1.

In exemplary embodiments, the thickness t1 of the second portion P2 of the encapsulating layer 300 may be greater than the thickness T1 of the solder plate 110 (i.e., t1>T1). Here, the thickness t1 of the second portion P2 of the encapsulating layer 300 may be a distance between the bottom surface of the lead frame 100 and the bottom surface 301 of the encapsulating layer 300. In other words, the second portion P2 of the encapsulating layer 300 may have a downwardly protruding structure, relative to the solder plate 110.

In certain embodiments, the thickness T1 of the solder plate 110 may be greater than the thickness t1 of the second portion P2 of the encapsulating layer 300 (i.e., t1<T1), like semiconductor package 3000 shown of FIG. 4. In other words, the solder plate 110 may have a downward protruding structure, relative to the second portion P2 of the encapsulating layer 300. In the case where the solder plate 110 is thicker than the second portion P2 of the encapsulating layer 300, the solder plate 110 may be more easily attached to the pads (not shown) of the printed circuit board (not shown).

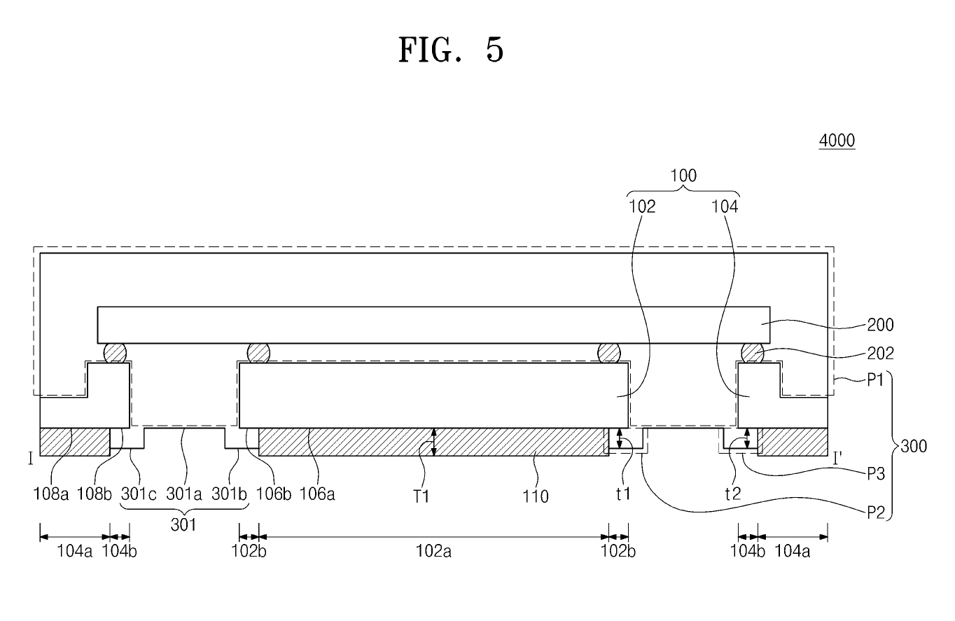

FIG. 5 is a sectional view, taken parallel to line I-I′ of FIG. 1, of a semiconductor package according to example embodiments of the inventive concept. For concise description, a previously described element may be identified by a similar or identical reference number without repeating an overlapping description thereof.

Referring to FIG. 5, a semiconductor package 4000 may include the lead frame 100, the semiconductor chip 200, and the encapsulating layer 300. The lead frame 100 may include the chip pad 102 and the lead 104. The chip pad 102 may include the center region 102a and the edge region 102b. The lead 104 may include the first region 104a and the second region 104b, and the second region 104b of the lead 104 may be disposed adjacent to the chip pad 102. The second region 104b of the lead 104 may be disposed between the edge region 102b of the chip pad 102 and the first region 104a of the lead 104.

The semiconductor chip 200 may be attached to the lead frame 100 in a flip-chip bonding manner The encapsulating layer 300 may be provided on the lead frame 100. For example, the encapsulating layer 300 may be provided to cover the semiconductor chip 200, to fill a space between the chip pad 102 and the lead 104, and to cover the bottom surface 106b of the edge region 102b of the chip pad 102 and the bottom surface 108b of the second region 104b of the lead 104.

The encapsulating layer 300 may include the first portion P1, the second portion P2, and a third portion P3. The first, second and third portions P1, P2, and P3 of the encapsulating layer 300 may be defined on the basis of a surface of the lead frame 100. For example, the first portion P1 of the encapsulating layer 300 may cover the top surface of the lead frame 100 and the semiconductor chip 200, and may fill the space between the chip pad 102 and the lead 104. The first portion P1 of the encapsulating layer 300 may include the bottom surface 301a. The bottom surface 301a of the first portion P1 of the encapsulating layer 300 may be substantially coplanar with the bottom surface 106b of the edge region 102b of the chip pad 102 and the bottom surface 108b of the second region 104b of the lead 104.

The second portion P2 of the encapsulating layer 300 may cover the bottom surface 106b of the edge region 102b of the chip pad 102. The second portion P2 of the encapsulating layer 300 may include a bottom surface 301b, which may be positioned at a different level from the bottom surface 301a of the first portion P1 of the encapsulating layer 300. For example, the bottom surface 301b of the second portion P2 of the encapsulating layer 300 may be positioned at a lower level than the bottom surface 301a of the first portion P1 of the encapsulating layer 300.

The third portion P3 of the encapsulating layer 300 may cover the bottom surface 108b of the second region 104b of the lead 104. The third portion P3 of the encapsulating layer 300 may include a bottom surface 301c, which may be positioned at a different level from the bottom surface 301a of the first portion P1 of the encapsulating layer 300. For example, the bottom surface 301c of the third portion P3 of the encapsulating layer 300 may be positioned at a lower level than the bottom surface 301a of the first portion P1 of the encapsulating layer 300. In one embodiment, the bottom surface 301b of the second portion P2 of the encapsulating layer 300 may be positioned at substantially the same level as the bottom surface 301c of the third portion P3 of the encapsulating layer 300. In another embodiment, however, the bottom surfaces 301b and 301c may be positioned at different levels. The second portion P2 of the encapsulating layer 300 may be spaced apart from the third portion P3 of the encapsulating layer 300 and, thus, a portion of the bottom surface 301a of the first portion P1 of the encapsulating layer 300 may be exposed between the second and third portions P2 and P3 of the encapsulating layer 300.

The solder plate 110 may be provided on the bottom surface of the lead frame 100. For example, the solder plate 110 may be provided on the bottom surface 106a of the center region 102a of the chip pad 102 and the bottom surface 108a of the first region 104a of the lead 104. The solder plate 110 may be provided to have a thickness of T1.

In some embodiments, the thickness T1 of the solder plate 110 may be greater than the thickness t1 of the second portion P2 of the encapsulating layer 300 (i.e., t1<T1). The thickness T1 of the solder plate 110 may be greater than the thickness t2 of the third portion P3 of the encapsulating layer 300 (i.e., t2<T1). In one embodiment, the second portion P2 of the encapsulating layer 300 may have substantially the same thickness as the third portion P3 of the encapsulating layer 300 (i.e., t1=t2). In another embodiment, the thicknesses t1 and t2 may be different. Here, the thickness t1 of the second portion P2 of the encapsulating layer 300 may be defined as a distance between the bottom surface 106b of the edge region 102b of the chip pad 102 and the bottom surface 301b of the second portion P2 of the encapsulating layer 300. The thickness t2 of the third portion P3 of the encapsulating layer 300 may be defined as a distance between the bottom surface 108b of the second region 104b of the lead 104 and the third bottom surface 301c of the encapsulating layer 300.

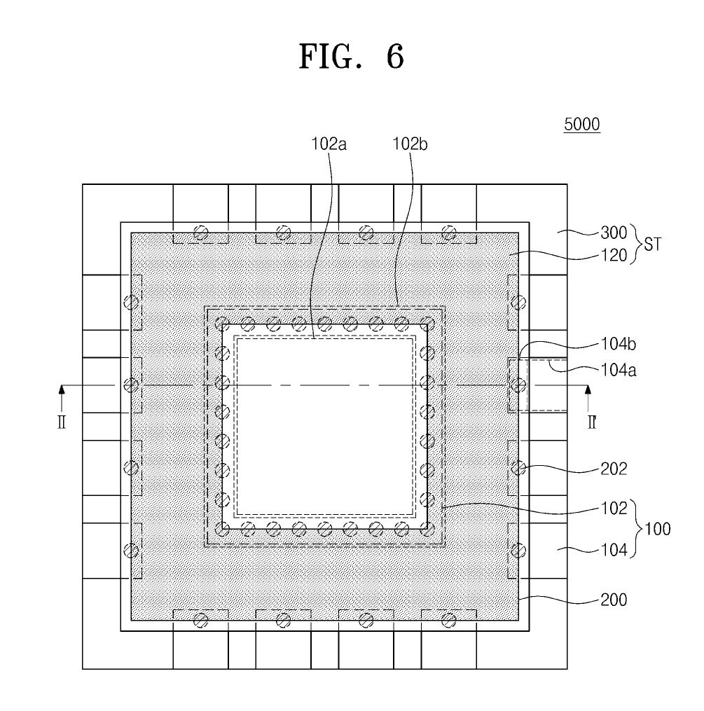

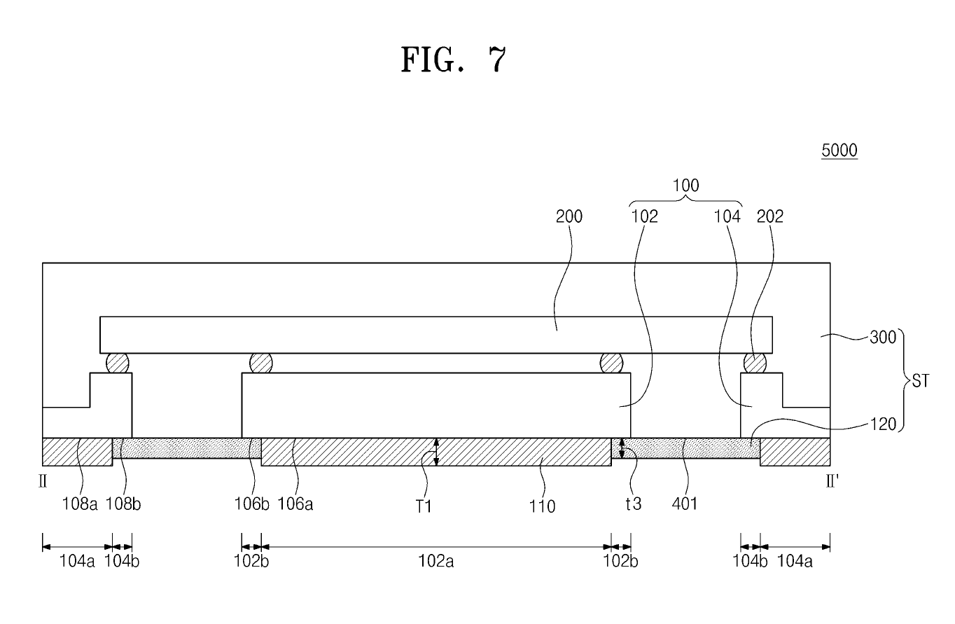

FIG. 6 is a plan view illustrating a semiconductor package according to an example embodiment of the inventive concept. FIG. 7 is a sectional view, taken parallel to line II-II′ of FIG. 6, of a semiconductor package according to an example embodiment of the inventive concept. For concise description, a previously described element may be identified by a similar or identical reference number without repeating an overlapping description thereof.

Referring to FIGS. 6 and 7, a semiconductor package 5000 may include the lead frame 100, the semiconductor chip 200, and a molding structure ST. The lead frame 100 may include the chip pad 102 and the lead 104. The chip pad 102 may include the center region 102a and the edge region 102b. The lead 104 may include the first region 104a and the second region 104b, and the second region 104b of the lead 104 may be disposed adjacent to the chip pad 102.

The semiconductor chip 200 may be provided on the lead frame 100. The semiconductor chip 200 may be attached to the lead frame 100 in a flip-chip bonding manner

The molding structure ST may be provided on the lead frame 100. The molding structure ST may include the encapsulating layer 300 and a resin film 120. The encapsulating layer 300 may cover the semiconductor chip 200 and fill a space between the chip pad 102 and the lead 104. The encapsulating layer 300 may include a top surface and a bottom surface 401. The bottom surface 401 of the encapsulating layer 300 may be substantially coplanar with the bottom surfaces of the chip pad 102 and the lead 104.

The encapsulating layer 300 may be formed on the lead frame 100 by a molding process using one or more resins, filler-containing epoxy mold compound (EMC) materials, or the like or any combination thereof. The filler may make it possible to reduce a difference in thermal expansion coefficient between the lead frame 100 and the semiconductor chip 200 and thereby to reduce a mechanical stress therebetween. The filler may be formed of, for example, silica or alumina.

The resin film 120 may be attached to the encapsulating layer 300, the lead 104 and the chip pad 102 to cover interfaces between the encapsulating layer 300 and the lead 104 and between the encapsulating layer 300 and the chip pad 102. For example, the resin film 120 may cover the bottom surface 106b of the edge region 102b of the chip pad 102 and the bottom surface 108b of the second region 104b of the lead 104. In this case, the resin film 120 may be in contact with substantially the entire surface of the bottom surface 401 of the encapsulating layer 300 that is exposed between the chip pad 102 and the lead 104. When viewed in plan view, the resin film 120 may have a ring-like shape (see, e.g., FIG. 6).

The resin film 120 may be an adhesive film, in which a resin (or a resin material) and a filler are contained. As an example, the filler contained in the resin film 120 may be the same material as the filler contained in the encapsulating layer 300. As another example, the filler contained in the resin film 120 may be a material different from the filler contained in the encapsulating layer 300. The filler may be formed of, for example, silica or alumina.

The solder plate 110 may be provided on the bottom surface of the lead frame 100. For example, the solder plate 110 may be provided on the bottom surface 106a of the center region 102a of the chip pad 102 and the bottom surface 108a of the first region 104a of the lead 104. The solder plate 110 may be provided to have a thickness of T1. The thickness T1 of the solder plate 110 may be greater than a thickness t3 of the resin film 120 (i.e., T1>t3). However, the thickness of the solder plate 110 is not limited to the example, in which the solder plate 110 is thicker the resin film 120. For example, the solder plate 110 may be provided to have a thickness that is smaller than or equal to that of the resin film 120.

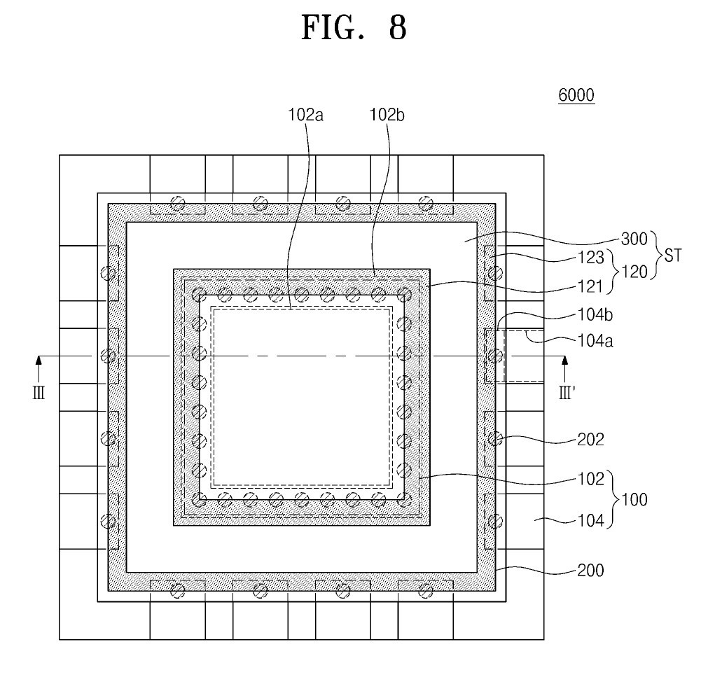

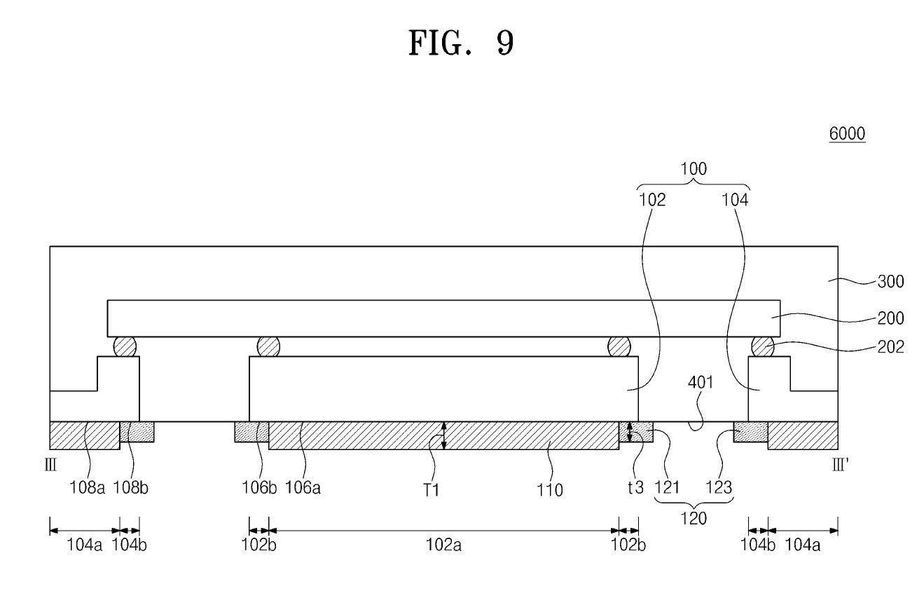

FIG. 8 is a plan view illustrating a semiconductor package according to an example embodiment of the inventive concept. FIG. 9 is a cross-sectional view, taken along line III-III′ of FIG. 8, of a semiconductor package according to an example embodiment of the inventive concept. For concise description, a previously-described element may be identified by a similar or identical reference number without repeating an overlapping description thereof.

Referring to FIGS. 8 and 9, in a semiconductor package 6000, the resin film 120 may include a first resin film 121 and a second resin film 123. The first resin film 121 may be attached to the encapsulating layer 300 and the chip pad 102 to cover an interface between the encapsulating layer 300 and the chip pad 102. The second resin film 123 may be attached to encapsulating layer 300 and the lead 104 to cover an interface between the encapsulating layer 300 and the lead 104. The first resin film 121 may be provided to cover the bottom surface 106b of the edge region 102b of the chip pad 102, and the second resin film 123 may be provided to cover the bottom surface 108b of the second region 104b of the lead 104. The first and second resin films 121 and 123 may be spaced apart from each other, and each of the first and second resin films 121 and 123 may cover a portion of the bottom surface 401 of the encapsulating layer 300 adjacent thereto. In this case, the remaining portion of the bottom surface 401 of the encapsulating layer 300 may be exposed between the first and second resin films 121 and 123.

When viewed in plan view, the resin film 120 may have a ring-like shape (see, e.g., FIG. 8). For example, each of the first and second resin films 121 and 123 may have a ring-like shape. In some embodiments, the second resin film 123 may be spaced apart from the first resin film 121 by a specific distance and, moreover, may enclose the first resin film 121.

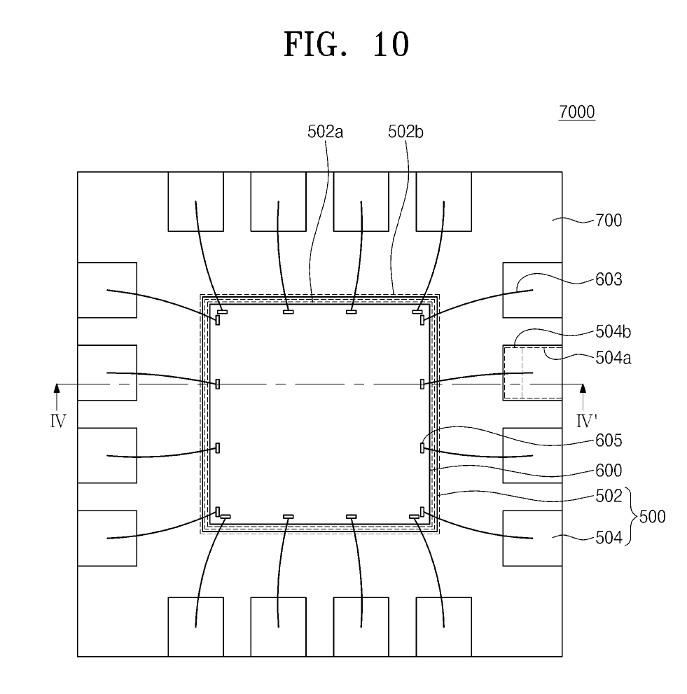

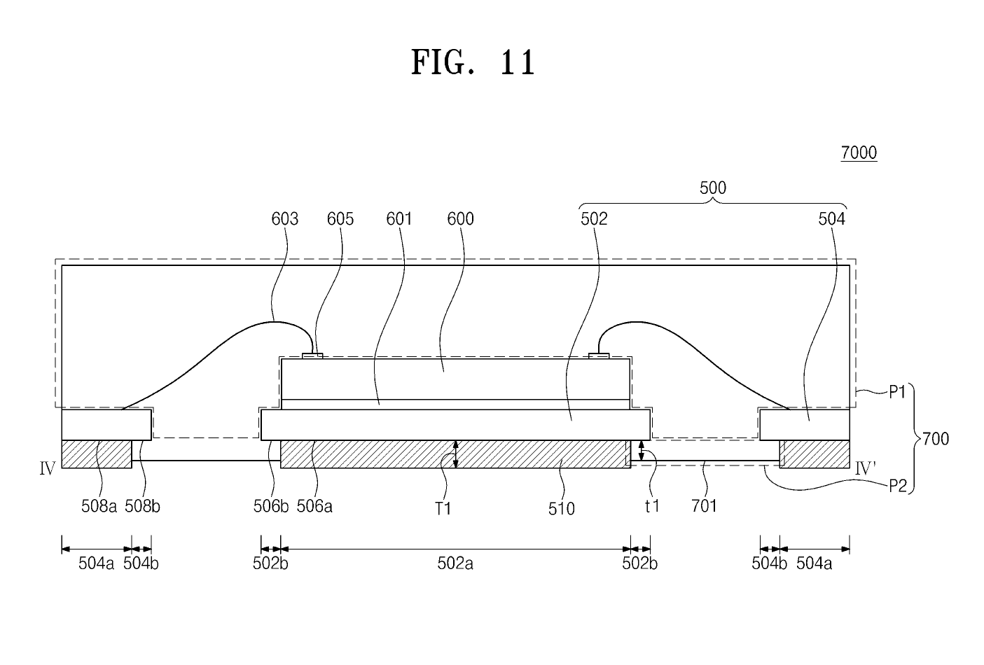

FIG. 10 is a plan view illustrating a semiconductor package according to an example embodiment of the inventive concept. FIG. 11 is a cross-sectional view, taken along line IV-IV′ of FIG. 10, of a semiconductor package according to an example embodiment of the inventive concept.

Referring to FIGS. 10 and 11, a semiconductor package 7000 may include a lead frame 500, a semiconductor chip 600, and an encapsulating layer 700. The lead frame 500 may include a chip pad 502 and leads 504. When viewed in plan view, the leads 504 may be disposed spaced apart from the chip pad 502 and may be arranged around or to enclose the chip pad 502.

The chip pad 502 may include a center region 502a and an edge region 502b around the center region 502a. Each of the leads 504 may include a first region 504a and a second region 504b, and the second region 504b of each lead 504 may be adjacent to the chip pad 502.

The semiconductor chip 600 may be mounted on the lead frame 500. For example, the semiconductor chip 600 may be adhered to the chip pad 502 by an adhesive layer 601. Bonding pads 605 may be provided on the semiconductor chip 600. The bonding pads 605 may be connected to the leads 104 through bonding wires 603. In other words, the semiconductor chip 600 and the lead frame 500 may be electrically connected to each other through the bonding wires 603. The bonding wires 603 may be formed of, or include a material such as gold (Au), etc.

The encapsulating layer 700 may be provided on the semiconductor chip 600. The encapsulating layer 700 may cover the semiconductor chip 600. The encapsulating layer 700 may fill a space between the chip pad 502 and the lead 504, and moreover, it may be extended to cover a bottom surface 506b of the edge region 502b of the chip pad 502 and a bottom surface 508b of the second region 504b of the lead 504. In one embodiment, the encapsulating layer 700 may be provided to have substantially the same features as the encapsulating layer 300 of FIG. 2 (e.g., a first portion P1, a second portion P2, etc.), and a detailed description thereof is, therefore, omitted.

A solder plate 510 may be provided on a bottom surface of the lead frame 500. For example, the solder plate 510 may be provided on a bottom surface 506a of the center region 502a of the chip pad 502 and a bottom surface 508a of the first region 504a of the lead 504. The solder plate 510 may be provided to have a thickness T1.

In some embodiments, the thickness T1 of the solder plate 510 may be greater than the thickness t1 of the second portion P2 of the encapsulating layer 700 (i.e., t1<T1). Here, the thickness t1 of the second portion P2 of the encapsulating layer 700 may be defined as a distance between the bottom surface of the lead frame 500 and a bottom surface 701 of the encapsulating layer 700.

According to example embodiments disclosed herein, a semiconductor package may be configured to have a lead frame with a chip pad and a lead, a semiconductor chip, and an encapsulating layer. The encapsulating layer may be provided to cover a bottom surface of an edge region of the chip pad and a bottom surface of a second region of the lead. This may make it possible to prevent stress from being concentrated at bottom interfaces between the encapsulating layer and the chip pad and between the encapsulating layer and the lead. Accordingly, it is possible to suppress or prevent failures, such as cracking and delamination, from occurring at the bottom interfaces and thereby to improve reliability of a semiconductor package. Furthermore, the encapsulating layer may be provided to fill a gap region between the chip pad and the leads spaced apart from each other and may be extended to at least partially cover the bottom surface of the chip pad and the bottom surfaces of the leads.

While example embodiments of the inventive concepts have been particularly shown and described, it will be understood by one of ordinary skill in the art that variations in form and detail may be made therein without departing from the spirit and scope of the attached claims.

What is claimed is:

1. A semiconductor package, comprising:
a lead frame comprising a chip pad and a lead, the chip pad including a center region and an edge region, the lead including a first region and a second region between the edge region of the chip pad and the first region of the lead;
a semiconductor chip disposed on the lead frame; and
an encapsulating layer disposed on the lead frame,
wherein the encapsulating layer covers the semiconductor chip and extends between the chip pad and the lead to cover a bottom surface of the edge region of the chip pad and a bottom surface of the second region of the lead.

2. The semiconductor package of claim 1, wherein the encapsulating layer is provided to expose the center region of the chip pad and the first region of the lead.

3. The semiconductor package of claim 1, further comprising a solder plate provided on a bottom surface of the center region of the chip pad and a bottom surface of the first region of the lead.

4. The semiconductor package of claim 3, wherein the encapsulating layer comprises:
a first portion covering the semiconductor chip and filling a space between the chip pad and the lead; and
a second portion disposed on the bottom surface of the edge region of the chip pad and the bottom surface of the second region of the lead,
wherein the solder plate is thicker than the second portion of the encapsulating layer.

5. The semiconductor package of claim 3, wherein the encapsulating layer comprises:
a first portion covering the semiconductor chip and filling a space between the chip pad and the lead; and
a second portion disposed on the bottom surface of the edge region of the chip pad and the bottom surface of the second region of the lead,
wherein the solder plate is thinner than the second portion of the encapsulating layer.

6. The semiconductor package of claim 1, wherein the encapsulating layer comprises:
a first portion covering the semiconductor chip and filling a space between the chip pad and the lead;
a second portion covering the bottom surface of the edge region of the chip pad; and
a third portion covering the bottom surface of the second portion of the lead,
wherein the second region of the encapsulating layer is spaced apart from the third portion of the encapsulating layer.

7. The semiconductor package of claim 6, wherein a bottom surface of the first portion of the encapsulating layer is partially exposed between the second portion of the encapsulating layer and the third portion of the encapsulating layer.

8. The semiconductor package of claim 1, wherein the lead frame comprises a plurality of the leads that are arranged around the edge region of the chip pad, wherein
the leads are provided below and overlapped with the semiconductor chip, and
the semiconductor package further comprises solder balls interposed between the semiconductor chip and the leads and between the semiconductor chip and the chip pad.

9. A semiconductor package, comprising:
a lead frame comprising a chip pad and a lead, the chip pad including a center region and an edge region, the lead including a first region and a second region between the edge region of the chip pad and the first region of the lead;
a semiconductor chip disposed on the lead frame;
an encapsulating layer provided on the lead frame to cover the semiconductor chip and fill a space between the chip pad and the lead; and
a resin film provided to cover interfaces between the chip pad and the encapsulating layer and between the lead and the encapsulating layer.

10. The semiconductor package of claim 9, wherein the resin film has a ring-like shape, when viewed in plan view.

11. The semiconductor package of claim 9, wherein the encapsulating layer, the chip pad, and the lead have bottom surfaces that are substantially coplanar with each other.

12. The semiconductor package of claim 9, wherein the resin film substantially wholly covers a bottom surface of the encapsulating layer.

13. The semiconductor package of claim 9, wherein the resin film comprises a first resin film and a second resin film, wherein
the first resin film covers a bottom surface of the edge region of the chip pad, and
the second resin film covers a bottom surface of the second region of the lead.

14. The semiconductor package of claim 13, wherein, when viewed in plan view, each of the first and second resin films has a ring-like shape and the second resin film is provided to enclose the first resin film.

15. The semiconductor package of claim 9, wherein the resin film is provided to expose the center region of the chip pad and the first region of the lead.

16. A semiconductor package, comprising:
a lead frame comprising a chip pad and a lead;
a semiconductor chip disposed on a top surface of the chip pad; and
a resin material covering the semiconductor chip and extending between the chip pad and the lead to cover a first region of a bottom surface of the chip pad and a bottom surface of the lead, wherein the bottom surface of the chip pad is opposite the top surface of the chip pad.

17. The semiconductor package of claim 16, wherein at least a portion of the resin material is included within an encapsulant layer covering the semiconductor chip and extending between the chip pad and the lead.

18. The semiconductor package of claim 17, wherein a bottom surface of the encapsulant layer is substantially coplanar with the first region of the bottom surface of the chip pad and the bottom surface of the lead, and wherein a portion of the resin material is included within a resin film, the resin film being disposed on the bottom surface of the encapsulant layer and at least one of the first portion of the bottom surface of the chip pad or the bottom surface of the lead.

19. The semiconductor package of claim 16, further comprising a solder plate on a second region of the bottom surface of the chip pad, wherein the second region is outside the first region.

20. The semiconductor package of claim 19, wherein a thickness of the solder plate is greater than a thickness of the resin material covering the first region of the bottom surface of the chip pad.
